(19) United States
(12) Patent Application Publication
(10) Pub. No.: US 2003/0096456 A1
(43) Pub. Date: May 22, 2003

(54) Method of manufacturing a semiconductor device

(75) Inventors: Shoshi Yasunaga, Fukuoka (JP); Hiroaki Narimatsu, Fukuoka (JP); Atsushi Fukui, Fukuoka (JP)

Correspondence Address: WOOD, PHILLIPS, KATZ, CLARK & MORTIMER, 500 W. MADISON STREET, SUITE 3800, CHICAGO, IL, 60661, US

(73) Assignee: Mitsui High-tec Inc.

(21) Appl. No.: 10/290,697

(22) Filed: Nov. 8, 2002

(30) Foreign Application Priority Data
Nov. 20, 2001 (JP) P. 2001-354753

(51) Int. Cl. H01L 21/44; H01L 21/48; H01L 21/50

(52) U.S. Cl. 438/124; 438/114; 438/115

(57) ABSTRACT

A method of manufacturing a semiconductor device. The method includes the steps of: providing a lead frame assembly with joined first and second unit lead frames, with the first unit lead frame having a first support and a plurality of leads and the second unit lead frame having a second support and a plurality of leads; mounting operating components on the first and second unit lead frames; applying a sealing composition over the lead frame assembly and the operating components to define a semiconductor preassembly; cutting the semiconductor preassembly so as to define first and second semiconductor devices, with the first and second semiconductor devices having first and second exposed edges respectively defined by cutting of the semiconductor preassembly; and moving at least the first semiconductor device against another element to break loose flash on the first exposed edge.

### BACKGROUND OF THE INVENTION

1. Field of the Invention

This invention relates to semiconductor devices and, more particularly, to a semiconductor device with a sealing composition in which components are embedded and through which conductive leads are exposed.

2. Background Art

One known form of semiconductor device has a conductive lead frame with components mounted thereon and covered by a sealing composition. To meet the increasing demand for reduced size, semiconductor devices of this type have been made in the form of SON (small outline non-leaded) and QFN (quad flat non-leaded) packages. In each of these designs, conductive leads are exposed at transverse side and bottom surfaces. An example of this type of prior art semiconductor device is shown at 10 in FIG. 5 herein.

A process for making this type of semiconductor device 10 is shown sequentially in FIGS. 1-5. In FIG. 1, a lead frame assembly is shown at 11 consisting of a matrix of individual unit lead frames 12, 14. The unit lead frames 12, 14 are interconnected through a te bar network. While two such lead frames 12, 14 are shown, typically, a matrix of four or more lead frames 12, 14 is formed. The matrix pattern may be struck from a conductive sheet 16. Alternatively, a strip of material can be utilized to form unit lead frames 12, 14 connected along a single row.

The unit lead frames 12,14 have the same construction. Exemplary unit lead frame 12 has a support 18 and a plurality of leads 20,21 therearound. As seen in FIG. 2, a semiconductor element 22 is applied to a surface 24 on the support 18. Through conductive elements/wires 26, the semiconductor element 22 is electrically connected to the leads 20, 21.

As shown in FIG. 3, with the conductive leads 26 operatively connected, a sealing resin 28 is applied atone side 30 of the lead frame assembly 11 over the semiconductor elements 22 and the wires 26. The semiconductor elements 22 and wires 26 thus become encapsulated. The sealing resin 28 is applied so as to extend continuously at a uniform thickness over all of the unit lead frames 12,14.

As shown in FIG. 4, plating, such as solder plating 32, is applied to the lead frame assembly 11, at the side 34 facing oppositely to the side 30. The solder plating 32 adheres to the exposed portions of the support 18 and the leads 20, 21. This results in a completed preassembly, shown at 36 in FIG. 4.

Once the preassembly 36 is completed, the preassembly 36 is cut, as shown in FIG. 5, as by a dicing saw, or the like. The cutting takes place along lines, indicated by arrows at 37, 38,40. The cutting along line 38 separates the semiconductor devices 10 from each other.

By resin-sealing continuously over the multiple unit lead frames 12, 14, the sealing process can be simplified. Assuming the external configuration is the same, various types of products can be accommodated using a single resin-forming mold. This potentially accounts for a significant reduction in manufacturing costs compared to those associated with manufacturing the devices individually.

However, during the cutting operation depicted in FIG. 5, flash 42 is produced at the exposed edges of the cut leads 20, 21. Aside from spoiling the appearance of the completed devices 10, the flash 42 potentially impairs the performance of the semiconductor device 10.

The leads 20, 21, in the process shown, are plated before the lead frame assembly 11 is cut, as shown in FIG. 5. Thus, the cut edges 44, 46 of the leads 20, 21 do not have any external plating thereon. As a result, visual inspection, such as solder joint confirmation after mounting of the semiconductor device 10, cannot be easily carried out. Additionally, the mounting characteristics of the exposed, cut edges 44, 46 may be different than for the plated surfaces of the lead frame assembly 11. As a result, the tenacity of bonding of elements to the edges 44, 46 on the completed device 10 may not be consistent and predictable.

### SUMMARY OF THE INVENTION

In one form, the invention is directed to a method of manufacturing a semiconductor device. The method includes the steps of: providing a lead frame assembly with joined first and second unit lead frames, with the first unit lead frame having a first support and a plurality of leads and the second unit lead frame having a second support and a plurality of leads; mounting operating components on the first and second unit lead frames; applying a sealing composition over the lead frame assembly and the operating components to define a semiconductor preassembly; cutting the semiconductor preassembly so as to define first and second semiconductor devices, with the first and second semiconductor devices having first and second exposed edges respectively defined by cutting of the semiconductor preassembly; and moving at least the first semiconductor device against another element to break loose flash on the first exposed edge.

The method may further include the step of plating the exposed edge of the first semiconductor device.

In one form, the step of moving at least the first semiconductor device involves vibrating or agitating the first semiconductor device.

The method may further include the step of placing the first semiconductor device in a container. In one form, the step of moving at least the first semiconductor device involves vibrating or agitating the container.

The method may include the step of placing the first semiconductor device in a container with another semiconductor device. In one form, the step of moving at least the first semiconductor device against another element involves moving at least the first semiconductor device against the another semiconductor device.

In one form, the step of plating the exposed edge of the first semiconductor device involves immersing the first semiconductor device in a plating solution.

In one form, the method includes the step of placing the first semiconductor device in a container with at least one other semiconductor device in a plating solution. The step of moving at least the first semiconductor device against another element may involve moving at least the first semiconductor device against the at least one other semiconductor device.

The method may further include the steps of immersing the first semiconductor device in a first liquid and thereafter removing the first semiconductor device from the first liquid and immersing the first semiconductor device in a plating solution.

The plating solution may be a precious metal.

In one form, the step of mounting operating components may involve mounting a first semiconductor element on the first support and electrically connecting the first semiconductor element to the leads on the first unit lead frame.

The step of applying a sealing composition may involve applying a resin material.

In one form, the step of providing a lead frame assembly involves providing a plurality of unit lead frames in addition to the first and second unit lead frames so that the first and second unit lead frames and the plurality of unit lead frames are joined in a matrix arrangement.

In one form, the step of plating the exposed edge of the first semiconductor device involves immersing the first semiconductor device in a plating fluid in a container and rotating the container.

In one form, the lead frame assembly is made from one of copper and copper alloy.

The step of cutting the semiconductor preassembly may be carried out using a cutting blade.

The invention is further directed to a method of manufacturing a semiconductor device including the steps of: providing a lead frame assembly with joined first and second unit lead frames, with the first unit lead frame having a first support and a plurality of leads and the second unit lead frame having a second support and a plurality of leads; mounting operating components on the first and second unit lead frames; applying a sealing composition over the lead frame assembly and the operating components to define a semiconductor preassembly; cutting the semiconductor preassembly so as to define first and second semiconductor devices, with the first and second semiconductor devices having first and second exposed edges respectively defined by cutting of the semiconductor preassembly; and plating the exposed edge of the first semiconductor device.

The plating step may involve immersing the first semiconductor device in a plating solution.

The method may further include the step of immersing the first semiconductor device in a first liquid. The plating step may involve immersing the first semiconductor device in a plating solution after removing the first semiconductor device from the first liquid.

The plating solution may be a precious metal.

The step of mounting operating components may involve mounting a first semiconductor element on the first support and electrically connecting the first semiconductor element to the leads on the first unit lead frame.

The step of applying a sealing composition may involve applying a resin material.

The step of providing a lead frame assembly may further involve providing a plurality of unit lead frames in addition to the first and second unit lead frames so that the first and second unit lead frames and the plurality of unit lead frames are joined in a matrix arrangement.

In one form, the step of plating the exposed edge of the first semiconductor device involves immersing the first semiconductor in a plating fluid in a container and rotating the container.

In one form, the lead frame assembly is made from one of copper and copper alloy.

The method may further include the step of placing the first semiconductor device in a container with a plating solution and at least another element and agitating the plating solution so that the first semiconductor device and the at least another element are caused to act against each other to break loose flash at the first exposed edge.

The at least another element may be a semiconductor device.

### BRIEF DESCRIPTION OF THE DRAWINGS

FIGS. 1-5 show sequentially the construction of semiconductor devices using a conventional process: FIG. 1 showing a lead frame assembly; FIG. 2 showing semiconductor elements attached to the lead frame assembly and electrically connected through wires to leads on the lead frame assembly; FIG. 3 showing resin applied to one side of the lead frame assembly so as to encase the semiconductor elements and wires electrically connecting the semiconductor elements to the unit lead frames; FIG. 4 showing external plating applied to the lead frame assembly on the side opposite that to which the resin material is applied to produce a preassembly; and FIG. 5 showing the preassembly cut to produce separate semiconductor devices;

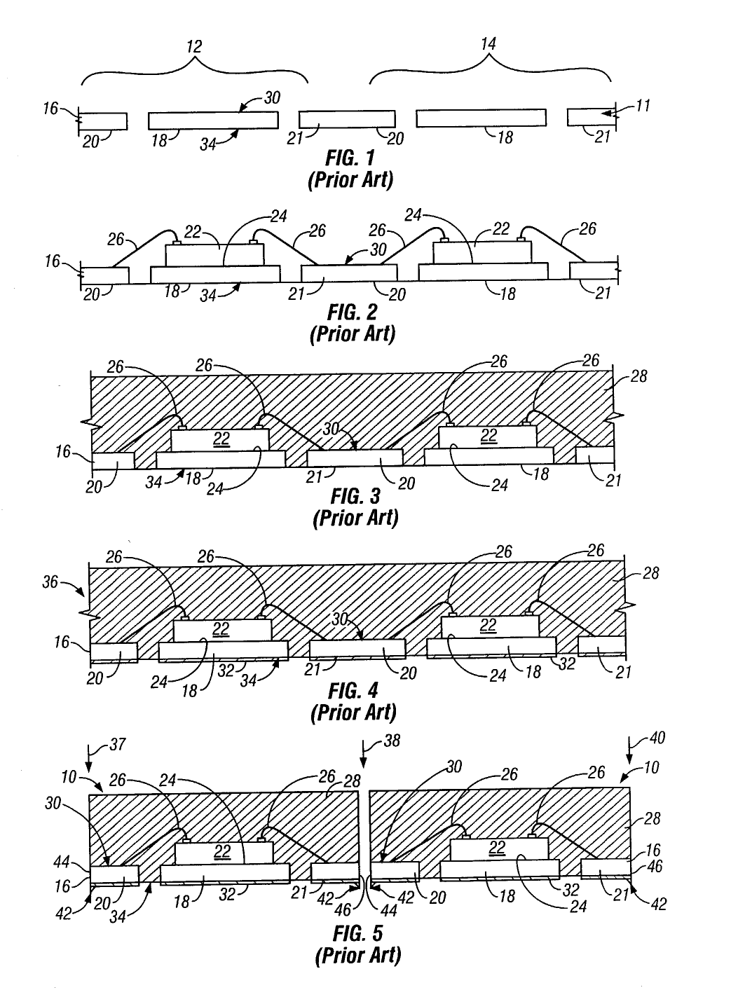

FIGS. 6-10 show sequentially the formation of semiconductor devices according to the present invention: FIG. 6 showing a lead frame assembly; FIG. 7 showing semiconductor elements attached and electrically connected to the lead frame assembly; FIG. 8 showing a sealing composition applied over one side of the semiconductor elements to produce a preassembly; FIG. 9 showing the preassembly cut to separate semiconductor devices from each other; and FIG. 10 showing plating on the exposed portion of the lead frame assembly including the edges exposed during the cutting shown in FIG. 9;

FIG. 11 is a plan view of the lead frame assembly in FIG. 6;

FIG. 12 is a schematic representation of a container for semiconductor devices which can be agitated/vibrated to break loose flash formed during cutting of the preassembly and to apply a plating material to exposed lead frame surfaces; and

FIG. 13 is a partial cross-sectional view of a semiconductor device, according to the present invention, and operatively connected to an apparatus.

### DETAILED DESCRIPTION OF THE DRAWINGS

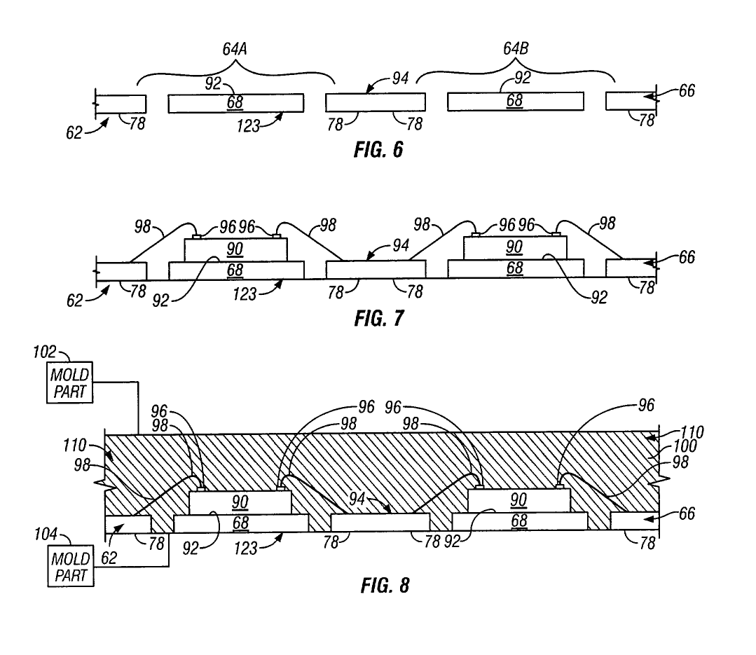

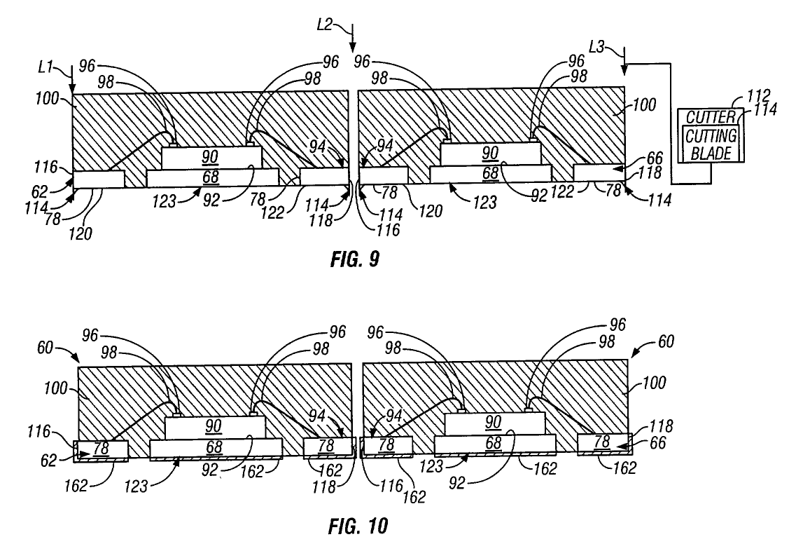

Referring initially to FIGS. 6-10, the sequential formation of semiconductor devices 60, according to the present invention, is depicted. The manufacturing process starts with the formation of a lead frame assembly 62, shown also in FIG. 11. The lead frame assembly 62 consists of a plurality of unit lead frames 64A, 64B, 64C, 64D, 64E, 64F, 64G, 64H, 64I, joined to each other in a 3×3 matrix pattern. The lead frame assembly 62 is cut from a conductive sheet 66, that may be copper or copper alloy, or other suitable material. Typically, the thickness of the sheet 66 is on the order of 0.12-0.15 millimeters.

The unit lead frames 64A-64I all have the same construction, though this is not a requirement. Exemplary unit lead frame 64A has a polygonal support 68, in this case shown as square. The square support 68 is bounded by a peripheral edge 69, defined by edge portions 70, 72, 74, 76.

Rectangular leads 78 are provided at each edge portion 70, 72, 74, 76. Five such leads 78 are shown at each edge portion 70, 72, 74, 76. However, the shape and number of the leads 78 is a design consideration which is not critical to the present invention. Through a tie bar network at 80, the leads 78 are maintained in a desired operative position relative to the edge portions 70, 72, 74, 76. Through the same tie bar network 80, the unit lead frames 64A-65I are interconnected to each other and to side rails 82, 84. The side rails 82, 84 have pilot holes 86 therein to facilitate controlled repositioning of the lead frame assembly 62.

It should be understood that the arrangement of unit lead frames shown at FIG. 11 is only exemplary. The invention can be practiced with as few as two joined unit lead frames and even on unit lead frames that are individually formed by a process different from that described herein.

As shown in FIG. 7, semiconductor elements 90 are applied to the unit lead frames 64A-65I. A semiconductor element 90 is applied to a mounting surface 92 on each support 68 on one side 94 of the lead frame assembly 62. This connection may be maintained using an adhesive, or the like. Electrode pads 96 on the semiconductor elements 90 are connected to the leads 78 through conductive elements, in this case wires 98. In the bonding region, a precious metal can be plated to increase the tenacity of the bonding of the wires 98 to the leads 78. Conventional flip-chip bonding can be used instead of the wire connection disclosed.

As shown in FIG. 8, a sealing resin 100 is then applied over the side 94 of the lead frame assembly 62 so as to encase the semiconductor elements 90 and the wires 98. The sealing resin may be an insulating material, such as epoxy, or the like. The resin material is formed in a predetermined shape between mold parts 102, 104. The resin is continuously formed through a uniform thickness over a squared region, as bounded by the dotted line 108 (FIG. 11) over the full matrix of unit lead frames 64A-65I. Once the resin is adhered, a unitary preassembly 110 is formed.

As shown in FIGS. 9 and 11, the preassembly 110 is cut along lines L1-L4 in one direction and along orthogonal lines L5-L8 to separate the semiconductor devices 60 from each other and the side rails 82, 84. As shown in FIG. 9, the cutting is carried out along exemplary line L3 through a cutter 112, which may be a dicing saw with a cutting blade 114. The lines L1-L8 bisect the leads 78 common to adjacent unit lead frames 64A-65I.

As a result of the cutting operation, the resin material 100 is removed and flash 114 is formed at the cut edges 116, 118 of the leads 78. The leads 78 in FIG. 9 are shown with the attached flash 114 and are unplated at both cut edges 116, 118 and exposed lead surfaces 120, 122, contiguous with and orthogonal to the edges 116, 118, respectively, and at the side 123 of the lead frame assembly 62 opposite to the side 94.

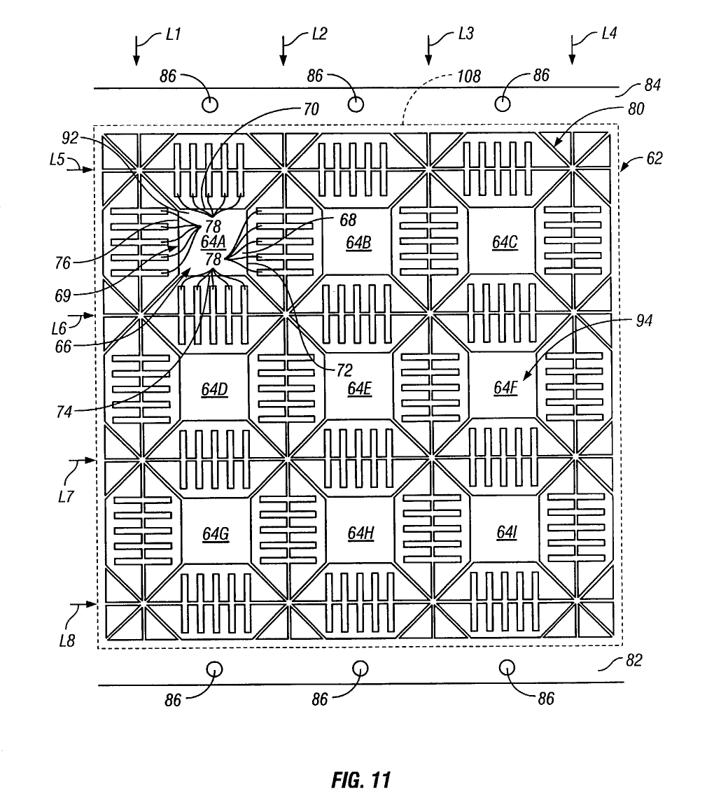

In the next manufacturing step, the individual semiconductor devices 60, in the FIG. 9 state, are placed in a container 124, shown in FIG. 12. The container 124 is in the form of a barrel. In this embodiment, the barrel 124 has an octagonal cross-sectional shape with a plurality of openings 128, one each in flat wall portions 130, 132, 134, 136, 138, 140, 142, 144 cooperatively defining an octagonally-shaped peripheral wall 146. The wall 146 bounds a receptacle 148 within which the semiconductor devices 60 are placed. The barrel 124 has a rotary shaft 150 which is driven around an axis 152 in the direction of the arrows 154.

Through a conveyor 156, the individual semiconductor devices 60 are fed serially into the receptacle 148 through an inlet (not shown). The majority of the volume of the barrel receptacle 148 is immersed in a supply of a plating solution 158, such as a precious metal. In this arrangement, the exposed surfaces 120, 122 and edges 116, 118 of the semiconductor devices 60 are plated with a solidified layer 162 of the plating liquid. One suitable plating is described in the Nikkan Kogyo Shimbunsha, September 1961 publication “Metal Surface Technology Handbook”, pp. 318-319. A device as described in Kokai No. Hei 1-168893 may also be used to effect plating. Other plating options are known to those skilled in this art.

By rotating the barrel 124, the semiconductor devices 60 are thoroughly exposed to the plating solution 158 so that there is effective uniform application of the plating material to the exposed lead surfaces 116,118,120,122. At the same time, by mixing the semiconductor devices 60 through rotation of the barrel 124, the action of the semiconductor devices 60, one against the other and the barrel wall 146, causes a substantial portion of the flash 114 to be removed from the semiconductor devices 60. The rotary motion of the barrel 124 is effective in causing the impacting of the semiconductor devices 60 against each other and the barrel 124. This action may be augmented by additional agitation or vibration of the container 124 or the plating solution 158 therewithin. To assure that this process removes adequately the detrimental flash 114, it is preferred that the material used for the lead frame assembly 62 be hardened and relatively brittle. By removing the flash 114, the consistency of appearance of the semiconductor devices 60 may be controlled. Further, dimensional deviations may be avoided which facilitates consistent mounting of the semiconductor devices 60, as hereinafter described.

In the event that the semiconductor devices 60 are relatively light in weight, they will be buoyed by the plating solution 158, which has a comparatively high specific gravity. As a result, it may take a considerable amount of agitation to effect a desired blending that results in the adequate removal of flash. To facilitate removal of the flash in a shorter time period, the barrel 124 can be used initially without immersion in the plating solution 158. Alternatively, the barrel 124 can be immersed in a liquid having a relatively low specific gravity so that the semiconductor devices become more completely immersed and blended in the liquid. Thereafter, the barrel 124 can be removed from the lower specific gravity liquid and placed in the desired plating solution 158.

Plating can also be carried out without using the container 124. The semiconductor devices 60 can be placed in a separate container 160, after or while removing the flash 114 by agitation. It is generally more economical if the semiconductor devices 60 can be simultaneously treated for flash removal and for plating.

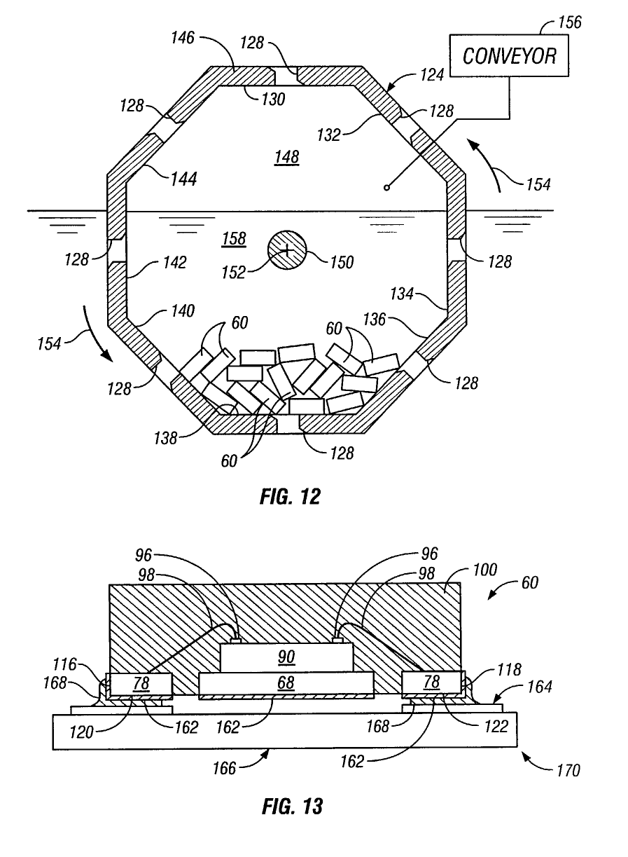

The completed semiconductor devices 60 are shown in FIGS. 10 and 13. In FIG. 13, the semiconductor device 60 is shown bonded to a circuit portion 164 of a printed substrate 166 using solder 168. The solder 168 adheres to the plating layer 162 at both the surfaces 120, 122 and cut edges 116, 118 of the leads 78. It is possible to thus visually confirm the solder placement after assembly. This may make possible consistent and secure bonding of the semiconductor device 60 to the printed substrate 166 for consistent manufacture of a high integrity product 170, as shown in FIG. 13.

The foregoing disclosure of specific embodiments is intended to be illustrative of the broad concepts comprehended by the invention.

1. A method of manufacturing a semiconductor device, the method comprising the steps of:
providing a lead frame assembly comprising joined first and second unit lead frames,
the first unit lead frame comprising a first support and a plurality of leads,
the second unit lead frame comprising a second support and a plurality of leads;
mounting operating components on the first and second unit lead frames;
applying a sealing composition over the lead frame assembly and the operating components to define a semiconductor preassembly;
cutting the semiconductor preassembly so as to define first and second semiconductor devices,
the first and second semiconductor devices having first and second exposed edges respectively defined by cutting of the semiconductor preassembly; and
moving at least the first semiconductor device against another element to break loose flash, on the first exposed edge.

2. The method of manufacturing a semiconductor device according to claim 1 further comprising the step of plating the exposed edge of the first semiconductor device.

3. The method of manufacturing a semiconductor device according to claim 1 wherein the step of moving at least the first semiconductor device comprises vibrating the first semiconductor device.

4. The method of manufacturing a semiconductor device according to claim 1 wherein the step of moving at least the first semiconductor device comprises agitating the first semiconductor device.

5. The method of manufacturing a semiconductor device according to claim 1 further comprising the step of placing the first semiconductor device in a container and wherein the step of moving at least the first semiconductor device comprises vibrating the container.

6. The method of manufacturing a semiconductor device according to claim 1 further comprising the step of placing the first semiconductor device in a container and wherein the step of moving at least the first semiconductor device comprises agitating the container.

7. The method of manufacturing a semiconductor device according to claim 1 further comprising the step of placing the first semiconductor device in a container with another semiconductor device and the step of moving at least the first semiconductor device comprises moving at least the first semiconductor device against the another semiconductor device.

8. The method of manufacturing a semiconductor device according to claim 2 wherein the step of plating the exposed edge of the first semiconductor device comprises immersing the first semiconductor device in a plating solution.

9. The method of manufacturing a semiconductor device according to claim 1 further comprising the step of placing the first semiconductor device in a container with at least one other semiconductor device and a plating solution and the step of moving at least the first semiconductor device comprises moving at least the first semiconductor device against the at least one other semiconductor device.

10. The method of manufacturing a semiconductor device according to claim 1 further comprising the step of immersing the first semiconductor device in a first liquid and thereafter removing the first semiconductor device from the first liquid and immersing the first semiconductor device in a plating solution to plate the first exposed edge.

11. The method of manufacturing a semiconductor device according to claim 2 wherein the plating solution comprises a precious metal.

12. The method of manufacturing a semiconductor device according to claim 1 wherein the step of mounting operating components comprises mounting a first semiconductor element on the first support and electrically connecting the first semiconductor element to the leads on the first unit lead frame.

13. The method of manufacturing a semiconductor device according to claim 1 wherein the step of applying a sealing composition comprises applying a resin material.

14. The method of manufacturing a semiconductor device according to claim 1 wherein the step of providing a lead frame assembly comprises providing a plurality of unit lead frames in addition to the first and second unit lead frames so that the first and second unit lead frames and the plurality of unit lead frames are joined in a matrix arrangement.

15. The method of manufacturing a semiconductor device according to claim 2 wherein the step of plating the exposed edge of the first semiconductor device comprises immersing the first semiconductor in a plating fluid in a container and rotating the container.

16. The method of manufacturing a semiconductor device according to claim 1 wherein the lead frame assembly comprises one of copper and copper alloy.

17. The method of manufacturing a semiconductor device according to claim 1 wherein the step of cutting the semiconductor preassembly comprises cutting using a cutting blade.

18. A method of manufacturing a semiconductor device, the method comprising the steps of:
providing a lead frame assembly comprising joined first and second unit lead frames,
the first unit lead frame comprising a first support and a plurality of leads,
the second unit lead frame comprising a second support and a plurality of leads;
mounting operating components on the first and second unit lead frames;
applying a sealing composition over the lead frame assembly and the operating components to define a semiconductor preassembly;
cutting the semiconductor preassembly so as to define first and second semiconductor devices,
the first and second semiconductor devices having first and second exposed edges respectively defined by cutting of the semiconductor preassembly; and
plating the exposed edge of the first semiconductor device.

19. A method of manufacturing a semiconductor device according to claim 18 wherein the step of plating the exposed edge of the first semiconductor device comprises immersing the first semiconductor device in a plating solution.

20. The method of manufacturing a semiconductor device according to claim 18 further comprising the step of immersing the first semiconductor device in a first liquid and the step of plating the exposed edge of the first semiconductor device comprises immersing the first semiconductor device in a plating solution after removing the first semiconductor device from the first liquid.

21. The method of manufacturing a semiconductor device according to claim 19 wherein the plating solution comprises a precious metal.

22. The method of manufacturing a semiconductor device according to claim 18 wherein the step of mounting operating components comprises mounting a first semiconductor element on the first support and electrically connecting the first semiconductor element to the leads on the first unit lead frame.

23. The method of manufacturing a semiconductor device according to claim 18 wherein the step of applying a sealing composition comprises applying a resin material.

24. The method of manufacturing a semiconductor device according to claim 18 wherein the step of providing a lead frame assembly comprises providing a plurality of unit lead frames in addition to the first and second unit lead frames so that the first and second unit lead frames and the plurality of unit lead frames are joined in a matrix arrangement.

25. The method of manufacturing a semiconductor device according to claim 18 wherein the step of plating the exposed edge of the first semiconductor device comprises immersing the first semiconductor device in a plating fluid in a container and rotating the container.

26. The method of manufacturing a semiconductor device according to claim 18 wherein the lead frame assembly comprises one of copper and copper alloy.

27. The method of manufacturing a semiconductor device according to claim 18 further comprising the step of placing the first semiconductor device in a container with a plating solution and at least another element, and agitating the plating solution so that the first semiconductor device and the at least another element are caused to act against each other to break loose flash on the first exposed edge.

28. The method of manufacturing a semiconductor device according to claim 27 wherein the at least another element comprises a semiconductor device.
